(19) United States
(12) Patent Application Publication
(10) Pub. No.: US 2013/0256709 A1
(43) Pub. Date: Oct. 3, 2013

(54) METHOD OF MANUFACTURING SUBSTRATE FOR LED MODULE AND SUBSTRATE FOR LED MODULE MANUFACTURED BY THE SAME

(71) Applicant: SAMSUNG ELECTRO-MECHANICS CO., LTD., Suwon (KR)

(72) Inventors: Yang Je Lee, Suwon (KR); Cheol Ho Heo, Suwon (KR); Dek Gin Yang, Suwon (KR); Kyoung Hwan Lim, Suwon (KR)

(73) Assignee: SAMSUNG ELECTRO-MECHANICS CO., LTD., Suwon (KR)

(21) Appl. No.: 13/793,828

(22) Filed: Mar. 11, 2013

(30) Foreign Application Priority Data
Mar. 28, 2012 (KR) 10-2012-0031796

(51) Int. Cl. H01L 33/08; H01L 21/02

(52) U.S. Cl. CPC H01L 33/08; H01L 21/02
USPC 257/88; 438/455

(57) ABSTRACT

Disclosed herein are a method of manufacturing a substrate for an LED module and a substrate for an LED module manufactured by the same, including: providing a base substrate having metal layers formed on both surfaces thereof; forming circuit patterns on the metal layers; applying a solder resist layer onto the circuit patterns; forming a through hole penetrating through the base substrate; separating the base substrate up and down; and bonding each of the separated base substrates to a parent substrate, thereby preventing light reflectivity of a parent substrate from being degraded due to a resist applying process and a surface treatment process.

### CROSS REFERENCE(S) TO RELATED APPLICATIONS

This application claims the benefit under 35 U.S.C. Section 119 of Korean Patent Application Serial No. 10-2012-0031796, entitled “Method Of Manufacturing Substrate For LED Module And Substrate For LED Module Manufactured By The Same” filed on Mar. 28, 2012, which is hereby incorporated by reference in its entirety into this application.

### BACKGROUND OF THE INVENTION

1. Technical Field

The present invention relates to a method of manufacturing a substrate for an LED module and a substrate for an LED module manufactured by the same, and more particularly, to a method of manufacturing a substrate for an LED module capable of maintaining light reflectivity of a parent substrate and a substrate for an LED module manufactured by the same.

2. Description of the Related Art

Recently, a light emitting diode (hereinafter, referred to as an LED) as a lighting and light emitting device capable of implementing lightness, thinness, and power saving has been interested. The LED element, which is an element that is light-emitted when forward current flows in a pn junction of semiconductor, is manufactured to use III-V group semiconductor crystal such as GaAs, GaN, and the like. Due to the development of an epitaxial growth technology of semiconductor and a light emitting element process technology, an LED having excellent conversion efficiency is developed and as a result, has been widely used in various applications.

The LED is integrally manufactured as a module. Meanwhile, the LED module is generally manufactured by applying a surface mounted technology (SMT) process to a general printed circuit board (PCB).

In the case of the printed circuit board (PCB) used for the LED module, the shape or material of the PCB needs to be manufactured to meet shape characteristics of the LED element, or the like. Therefore, the printed circuit board (PCB) uses materials having good rigidity and small thermal deformation. In particular, light from the LED element has straightness and as a result, the LED elements need to be manufactured using separate members, such as a reflector, a light-guide plate, and the like, according to a type in which devices are mounted on the PCB. That is, when the LED elements are mounted on the existing PCB, a predetermined amount of light is lost due to the straightness characteristics of the LED light and therefore, efficiency may be degraded.

Therefore, in the PCB used for the LED module, an aluminum material having excellent light reflectivity has been used as the parent substrate. In addition, in order to implement the more excellent light reflectivity, the surface of the parent substrate is subjected to mirror processing.

In connection with this, Korean Patent Laid-Open Publication No. 10-2010-0123155 (hereinafter, Prior Art document) has proposed a printed circuit board for an LED module including a reflecting layer in consideration of the LED characteristics.

However, reviewing claims of the Prior Art Document, similarly to a process of manufacturing a general printed circuit board according to the related art, processes of forming circuit patterns on a parent substrate (or a base substrate) and applying photoresist to the circuit patterns are performed. According to the general printed circuit board of the related art, the parent substrate is damaged and thus, the light reflectivity is degraded.

That is, in the state in which the circuit patterns are generated on the parent substrate, a process of applying resist to the entire substrate. In this case, the parent substrate may be damaged due to the applied resist.

In addition, a surface treatment process may be applied to the circuit patterns exposed for wire bonding of the substrate and the LED element in the LED module. According to the manufacturing process of the related art even during the surface treatment process, the surface treatment is applied to the entire substrate in the state in which the circuit patterns are generated on the parent substrate and thus, the parent substrate may be damaged.

### PRIOR ART DOCUMENT

### Patent Document

(Patent Document 1) Korean Patent Laid-Open Publication No. 10-2010-0123155

### SUMMARY OF THE INVENTION

An object of the present invention is to provide a method of manufacturing a substrate for an LED module and a substrate for an LED module manufactured by the same capable of maintaining light reflectivity of a parent substrate.

According to an exemplary embodiment of the present invention, there is provided a method of manufacturing a substrate for an LED module, including: providing a base substrate having metal layers formed on both surfaces thereof; forming circuit patterns on the metal layers; applying a solder resist layer onto the circuit patterns; separating the base substrate up and down; and bonding each of the separated base substrates to a parent substrate.

The method of manufacturing a substrate for an LED module may further include: after the applying of the solder resist layer onto the circuit patterns, performing a surface treatment process on the exposed circuit patterns.

The method of manufacturing a substrate for an LED module may further include: forming a through hole penetrating through the base substrate at the time of forming the circuit patterns on the metal layer.

The method of manufacturing a substrate for an LED module may further include: after the bonding of each of the separated base substrates to the parent substrate, plating an opened region by the through hole in the parent substrate.

The bonding of each of the separated base substrates to the parent substrate may be performed by temporarily bonding a bonding sheet between the base substrate and the parent substrate.

According to another exemplary embodiment of the present invention, there is provided a method of manufacturing a substrate for an LED module, including: providing two sheets of base substrates having metal layers formed on surfaces thereof; bonding the two sheets of base substrates to each other by attaching a release film between the two sheets of base substrates disposed so that one surfaces thereof on which the metal layers are not formed face each other; forming circuit patterns on the metal layers; applying a solder resist layer onto the circuit patterns; separating the two sheets of base substrates by peeling off the release film; and bonding each of the separated base substrate to a parent substrate.

The method of manufacturing a substrate for an LED module may further include: after the applying of the solder resist layer onto the circuit patterns, performing a surface treatment process on the exposed circuit patterns.

The method of manufacturing a substrate for an LED module may further include: forming a through hole penetrating through the base substrate at the time of forming the circuit patterns on the metal layer.

The method of manufacturing a substrate for an LED module may further include: after the bonding of each of the separated base substrates to the parent substrate, plating an opened region by the through hole in the parent substrate.

According to another exemplary embodiment of the present invention, there is provided a substrate for an LED module, including: a parent substrate; a base substrate formed in a portion except for a region of the parent substrate in which LED elements are mounted; a metal layer provided on the base substrate and formed with circuit patterns; a solder resist layer formed on the metal layer; and a plating layer provided in the region of the parent substrate in which the LED elements are mounted.

The parent substrate may be made of an aluminum material.

The substrate for an LED module may further include: a bonding sheet bonded between the base substrate and the parent substrate.

### BRIEF DESCRIPTION OF THE DRAWINGS

FIGS. 1 to 6 are process diagrams showing a method of manufacturing a substrate for an LED module according to an exemplary embodiment of the present invention.

FIGS. 7 to 13 are process diagrams showing a method of manufacturing a substrate for an LED module according to another exemplary embodiment of the present invention.

FIG. 14 is a cross-sectional view of a substrate for an LED module manufactured by the method of manufacturing a substrate for an LED module according to the exemplary embodiment of the present invention.

### DESCRIPTION OF THE PREFERRED EMBODIMENTS

Various advantages and features of the present invention and methods accomplishing thereof will become apparent from the following description of embodiments with reference to the accompanying drawings. However, the present invention may be modified in many different forms and it should not be limited to the embodiments set forth herein. These embodiments may be provided so that this disclosure will be thorough and complete, and will fully convey the scope of the invention to those skilled in the art. Like reference numerals throughout the description denote like elements.

Terms used in the present specification are for explaining the embodiments rather than limiting the present invention. Unless explicitly described to the contrary, a singular form includes a plural form in the present specification. The word “comprise” and variations such as “comprises” or “comprising,” will be understood to imply the inclusion of stated constituents, steps, operations and/or elements but not the exclusion of any other constituents, steps, operations and/or elements.

Hereinafter, a configuration and an acting effect of exemplary embodiments of the present invention will be described in more detail with reference to the accompanying drawings.

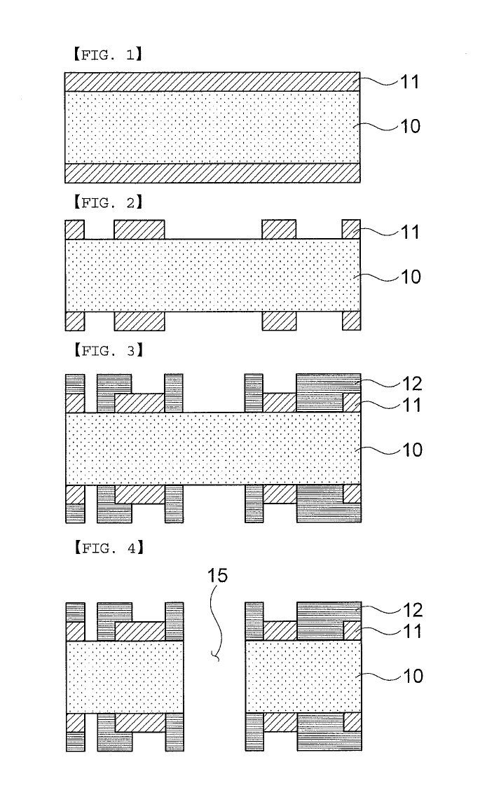

FIGS. 1 to 6 are process diagrams showing a method of manufacturing a substrate for an LED module according to an exemplary embodiment of the present invention.

As shown in FIG. 1, a method of manufacturing a substrate for an LED module according to an exemplary embodiment of the present invention includes providing a base substrate 10 having metal layers 11 formed at both surfaces thereof.

In this configuration, the base substrates 10 are a layer that is bonded to a parent substrate (13 of FIG. 6 during the subsequent processes and is made of adhesive resin such as PREPREG, and the like, to isolate between the metal layer 11 and the parent substrate 13.

The base substrates 10 are separated up and down during the subsequent processes and therefore, may be preferably provided at a thickness within an appropriate range.

In addition, the substrate for the LED module needs to efficiently emit heat diffused from the LED element and therefore, the base substrate 10 may be made of epoxy or silicon resin filled with thermal conductive particles so as to increase thermal conductivity.

The metal layers 11 formed on both surfaces of the base substrate 10 may be made of any one of Cu, Ag, Sn, Au, Ni, and Pd and may be formed by any one of electroless plating, electroplating, screen printing, sputtering, evaporation, inkjetting, and dispensing or a combination thereof.

Next, as shown in FIG. 2, a process of forming circuit patterns on the metal layers 11 is performed.

The circuit patterns may be formed by any one of photolithography, E-beam lithography, focused ion beam lithography, dry etching, wet etching, and nano-imprint that use processes of bonding a photosensitive film having predetermined patterns to the metal layer 11 and then, applying processes such as exposing, developing, etching, and the like, thereto.

Next, as shown in FIG. 3, a process of applying solder resist layers 12 onto the circuit patterns is performed.

The solder resist layer 12 is a layer to prevent the circuit patterns and the surface of the base substrate 10 from being corroded or damaged due to external environment. In this case, the resist has various colors, but the exemplary embodiment of the present invention applies white photo solder resist (PSR) so as to reduce light absorptance. In this case, it is preferable to perform applying, except for a region in which the LED element is mounted.

Meanwhile, the method of manufacturing a substrate for an LED module according to the exemplary embodiment of the present invention may further perform a process of applying the solder resist layer 12 onto the circuit patterns and then, applying the surface treatment process to the exposed circuit patterns.

The surface treatment process is to perform the wire bonding between the LED substrate and the LED element without leading a separate leading wire. The surface treatment process is applied to the circuit patterns exposed to the outside by any one of organic solder preserve (OSP), electroless nickel immersion gold (ENIG), and electroless nickel electroless palladium immersion gold (ENEPIG). According to the surface treatment process, a substrate having high difficulty can be manufactured and more LED elements can be mounted on the substrate having a smaller size.

As described above, unlike the method of manufacturing a substrate for an LED module according to the related art, according to the method of manufacturing a substrate for an LED module according to the exemplary embodiment of the present invention, a process of applying the solder resist layer 12 is performed in the state in which the substrate is not bonded to the parent substrate 13. Therefore, unlike the manufacturing method according to the related art, the exemplary embodiment of the present invention can prevent the parent substrate 13 from being damaged due to the process of applying a solder resist layer and thus, maintain the light reflectivity of the parent substrate 13.

In addition, even when the surface treatment process is performed, the surface treatment process is performed in the state in which the substrate is not bonded to the parent substrate 13, thereby making it possible to prevent the parent substrate 13 from being damaged due to the surface treatment process and maintain the light reflectivity of the parent substrate 13, unlike the manufacturing method of the related art.

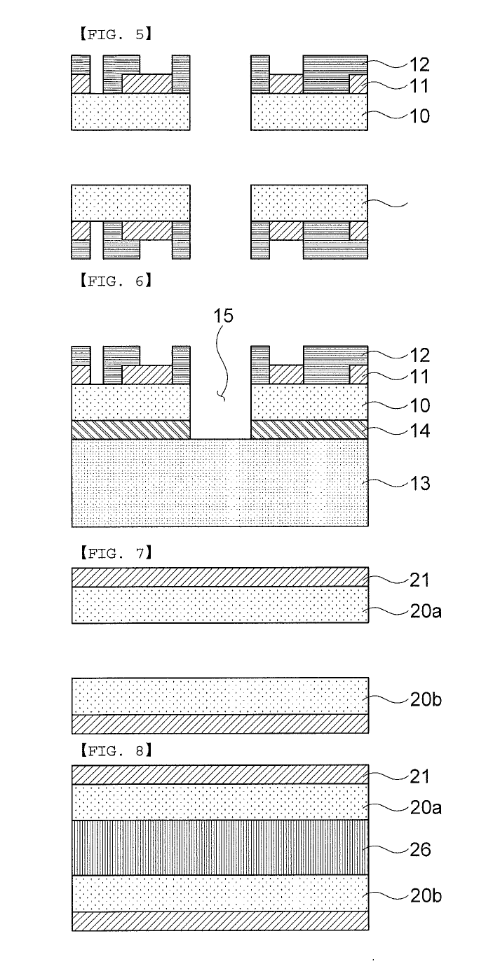

Next, as shown in FIG. 4, a process of forming a through hole 15 penetrating through the base substrate 10 is performed.

The through hole 15 is a space for a region of the parent substrate 13 in which the LED elements are mounted. In this case, the through hole 15 may be formed by drilling working, such as computer numerical control (CNC) drill, CO₂ or Yag laser drill, and the like, or by a router method including a CNC router machine or a router bit.

Next, as shown in FIG. 5, a process of separating the base substrate 10 up and down is performed. That is, a middle of the base substrate 10 is cut using a router, and the like. Therefore, two sheets of base substrates on which the circuit patterns and the solder resist layer 12 are mounted may be formed.

Finally, as shown in FIG. 6, the substrate for the LED module may be finally completed by performing a process of bonding each of the separated base substrates 10 to the parent substrate 13. FIG. 6 shows the state in which one base substrate 10 is bonded to the parent substrate 13. As shown in FIG. 6, another base substrate may be bonded to another parent substrate.

As described above, a process of bonding each of the separated based substrates 10 to the parent substrate 13 may be performed by temporarily bonding a bonding sheet 14 between the base substrate 10 and the parent substrate 13. As a material of the bonding sheet 14, epoxy-based thermosetting resin or prepregs-based materials may be used.

In addition, the method of manufacturing a substrate for an LED module according to the exemplary embodiment of the present invention may further perform bonding each of the separated base substrates 10 to the parent substrate 13 and then, plating the region of the parent substrate 13 in which the LED elements are mounted.

Therefore, the plating layer for reflecting light emitted from the LED elements may be formed on the region of the parent substrate 13 in which the LED elements are mounted, that is, a top of the parent substrate 13 exposed by the through hole 15 in FIG. 5.

The plating layer may preferably use metals having high reflectivity of light. Representatively, silver (Ag), gold (Au), or tin (Sn), and the like, may be selected. The plating layer may be may be formed by any one of electroless plating, electroplating, screen printing, sputtering, evaporation, inkjetting, and dispensing or a combination thereof by using any one of Cu, Ag, Sn, Au, Ni, and Pd.

Hereinafter, the method of manufacturing a substrate for an LED module according to another exemplary embodiment of the present invention will be described.

FIGS. 7 to 13 are process diagrams showing a method of manufacturing a substrate for an LED module according to another exemplary embodiment of the present invention.

As shown in FIG. 7, a method of manufacturing a substrate for an LED module according to another exemplary embodiment of the present invention includes providing two sheets of base substrates 20a and 20b having the metal layers 21 formed on one surface thereof.

Herein, the base substrates 20a and 20b are a layer bonded to the parent substrate (23 of FIG. 13) during the subsequent processes and may be made of adhesive resin such as PREPREG, and the like. Further, the base substrates 20a and 20b serves to isolate between the metal layer 21 and the parent substrate 23.

The metal layers 21 formed on surfaces of the base substrates 20a and 20b may be made of any one of Cu, Ag, Sn, Au, Ni, and Pd and may be formed by any one of electroless plating, electroplating, screen printing, sputtering, evaporation, inkjetting, and dispensing or a combination thereof.

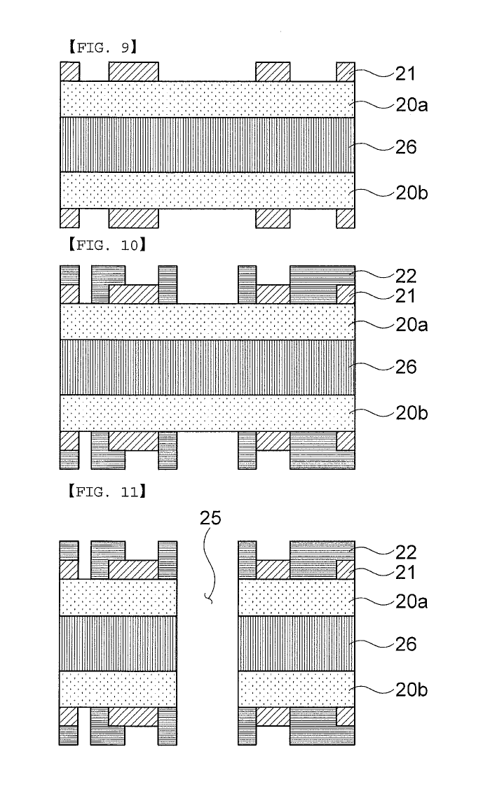

Next, as shown in FIG. 8, one surfaces of two sheets of base substrates 20a and 20b on which the metal layers 21 are not formed are disposed so as to face each other and then, a release film 26 is attached therebetween to perform a process of bonding the two sheets of base substrates 20a and 20b to each other.

The release film 26 may be made of resin-based resin, and the like. Therefore, in the subsequent process, a sharp knife is inserted between the release film 26 and each of the base substrates 20a and 20b and then, when slight shearing force is applied therebetween, the release film 26 is easily peeled off.

Next, as shown in FIG. 9, a process of forming circuit patterns on the metal layers 21 is performed. The method of forming the circuit patterns is already described and therefore, the detailed description thereof will be omitted below.

Next, as shown in FIG. 10, an applying the solder resist layer 22 for preventing the circuit patterns and the surfaces of the base substrates 20a and 20b from being corroded and damaged due to external environment is performed.

As described above, at the time of applying the solder resist layer 22, the white photo solder resist (PSR) is used and the applying is preferably performed, except for the region in which the LED elements are mounted.

In addition, the method of manufacturing a substrate for an LED module according to another exemplary embodiment of the present invention may further perform a process of applying the solder resist layer 22 onto the circuit patterns and then, a process of applying the surface treatment process to the exposed circuit patterns.

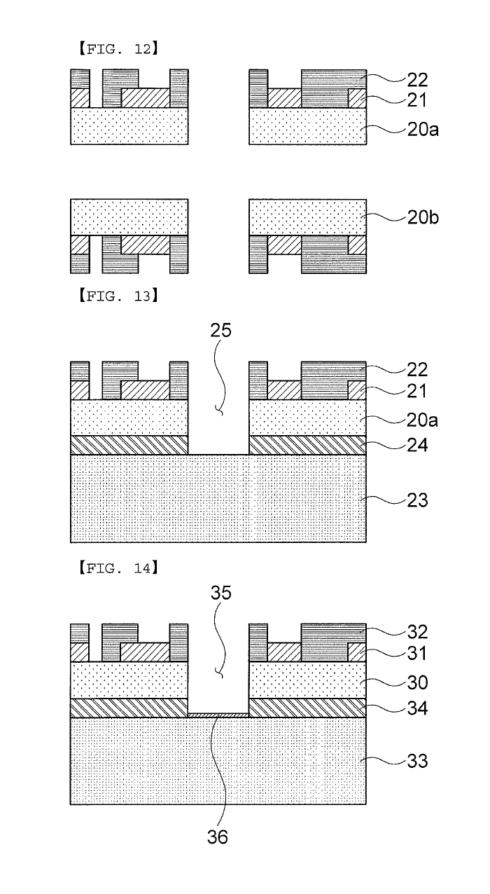

Next, as shown in FIG. 11, a process of forming a through hole 25 for the region of the parent substrate 23 in which the LED elements are mounted is performed. The method of forming the through hole 25 is already described and therefore, the detailed description thereof will be omitted.

Next, as shown in FIG. 12, a process of peeling off the release film 26 to separate the two sheets of base substrates 20a and 20b as described above is performed.

Finally, as shown in FIG. 13, the substrate for an LED module can be completed by bonding each of the separated base substrates 20a and 20b to the parent substrate 23. This can be formed by temporarily bonding a bonding sheet 24 made of the epoxy-based thermosetting resin or the prepregs-based material between the base substrates 20a and 20b and the parent substrate 23.

In addition, the method of manufacturing a substrate for an LED module according to another exemplary embodiment of the present invention may further perform bonding each of the separated base substrates 20a and 20b to the parent substrate 23 and then, plating the region of the parent substrate 23 in which the LED elements are mounted.

Hereinafter, the substrate for an LED module manufactured by the method of manufacturing a substrate for an LED module according to the exemplary embodiment of the present invention will be described.

FIG. 14 is a cross-sectional view of a substrate for an LED module manufactured by the method of manufacturing a substrate for an LED module according to the exemplary embodiment of the present invention.

Referring to FIG. 14, the substrate for an LED module manufactured by the method of manufacturing a substrate for an LED module according to the exemplary embodiment of the present invention may include a parent substrate 33, a base substrate 30, a metal layer 31, a solder resist layer 32, and a plating layer 36.

Here, the parent substrate 33 may be a metal substrate made of an aluminum material. In the case of the metal substrate, the substrate has small deformation due to heat emitted from the LED elements and has excellent thermal conductivity and efficiently emits heat generated from the LED elements. However, the exemplary embodiment of the present invention is not limited to the metal substrate and it is to be noted that the existing epoxy resin or polyimide-based substrate may be used as the parent substrate according to the characteristics of the LED elements.

The base substrate 30 is mounted on the parent substrate 30, except for the region in which the LED elements are mounted. That is, the base substrate 30 is provided with a through hole 35 for the LED element mounting space.

The base substrate 30 is made of adhesive resin such as PREPREG, and the like, to isolate between the metal layer 31 and the parent substrate 33.

The metal layer 31 is provided on the base substrate 30 and is provided with circuit patterns.

The solder resist layer 32 is formed on the metal layer 31 to protect the metal layer 31 and the surface of the base substrate 30 from the outside. The resist has various colors, but in the exemplary embodiment of the present invention, it is preferable to use the white photo solder resist (PSR) so as to reduce the light absorptance.

The plating layer 36 is provided in the region of the parent substrate 33 in which the LED elements are mounted.

Generally, unlike the general printed circuit board in the case of the substrate for an LED module, in order to increase the light reflectivity, the separate process, for example, the mirror processing is performed on the surface of the parent substrate, thereby increasing the manufacturing costs. However, the substrate for an LED module according to the exemplary embodiment of the present invention may remove the separate processes so as to increase the light reflectivity by including the plating layer 36 in the region in which the Led elements are mounted. Accordingly, this can save the manufacturing costs, simplify the manufacturing process, and shorten the manufacturing lead time.

Meanwhile, in order to increase the adhesion between the base substrate 30 and the parent substrate 33, a bonding sheet 34 made of the epoxy-based thermosetting resin or the prepreg-based material may be further provided between the base substrate 30 and the parent substrate 33.

According to the method of manufacturing a substrate for an LED module of the exemplary embodiments of the present invention, the process of applying a solder resist layer is performed in the state in which the substrate is not bonded to the parent substrate, thereby making it possible to prevent the parent substrate from being damaged due to the process of applying the solder resist layer and maintain the light reflectivity of the parent substrate, unlike the manufacturing method of the related art.

In addition, the surface treatment process is applied to the circuit patterns in the state in which the substrate is not bonded to the parent substrate, thereby making it possible to prevent the parent substrate from being damaged due to the surface treatment process and maintain the light reflectivity of the parent substrate, unlike the manufacturing method of the related art.

Further, according to the substrate for the LED module manufactured by the method of manufacturing a substrate for an LED module of the present invention, the separate plating layer is mounted on the region of the parent substrate in which the Led elements are mounted to remove the mirror processing so as to increase the light reflectivity of the parent substrate, thereby making it possible to save the manufacturing costs and shorten the manufacturing lead time.

The above detailed description exemplifies the present invention. Further, the above contents just illustrate and describe preferred embodiments of the present invention and the present invention can be used under various combinations, changes, and environments. That is, it will be appreciated by those skilled in the art that substitutions, modifications and changes may be made in these embodiments without departing from the principles and spirit of the general inventive concept, the scope of which is defined in the appended claims and their equivalents. Although the exemplary embodiments of the present invention have been disclosed for illustrative purposes, those skilled in the art will appreciate that various modifications, additions and substitutions are possible, without departing from the scope and spirit of the invention as disclosed in the accompanying claims. Therefore, the detailed description of the present invention does not intend to limit the present invention to the disclosed embodiments. Further, it should be appreciated that the appended claims include even another embodiment.

What is claimed is:

1. A method of manufacturing a substrate for an LED module, comprising:
providing a base substrate having metal layers formed on both surfaces thereof;
forming circuit patterns on the metal layers;
applying a solder resist layer onto the circuit patterns;
separating the base substrate up and down; and
bonding each of the separated base substrates to a parent substrate.

2. The method according to claim 1, further comprising, after the applying of the solder resist layer onto the circuit patterns, performing a surface treatment process on the exposed circuit patterns.

3. The method according to claim 1, further comprising forming a through hole penetrating through the base substrate at the time of forming the circuit patterns on the metal layer.

4. The method according to claim 3, further comprising, after the bonding of each of the separated base substrates to the parent substrate, plating an opened region by the through hole in the parent substrate.

5. The method according to claim 1, wherein the bonding of each of the separated base substrates to the parent substrate is performed by temporarily bonding a bonding sheet between the base substrate and the parent substrate.

6. A method of manufacturing a substrate for an LED module, comprising:
providing two sheets of base substrate having metal layers formed on surfaces thereof;
bonding the two sheets of base substrates to each other by attaching a release film between the two sheets of base substrates disposed so that one surfaces thereof on which the metal layers are not formed face each other;
forming circuit patterns on the metal layers;
applying a solder resist layer onto the circuit patterns;
separating the two sheets of base substrates by peeling off the release film; and
bonding each of the separated base substrate to a parent substrate.

7. The method according to claim 6, further comprising, after the applying of the solder resist layer onto the circuit patterns, performing a surface treatment process on the exposed circuit patterns.

8. The method according to claim 6, further comprising forming a through hole penetrating through the base substrate at the time of forming the circuit patterns on the metal layer.

9. The method according to claim 8, further comprising, after the bonding of each of the separated base substrates to the parent substrate, plating an opened region by the through hole in the parent substrate.

10. A substrate for an LED module, comprising:
a parent substrate;
a base substrate formed in a portion except for a region of the parent substrate in which LED elements are mounted;
a metal layer provided on the base substrate and formed with circuit patterns;
a solder resist layer formed on the metal layer; and
a plating layer provided in the region of the parent substrate in which the LED elements are mounted.

11. The substrate for an LED module according to claim 10, wherein the parent substrate is made of an aluminum material.

12. The substrate for an LED module according to claim 10, further comprising a bonding sheet bonded between the base substrate and the parent substrate.
